(19) United States
(12) Patent Application Publication
(10) Pub. No.: US 2021/0259103 A1
(43) Pub. Date: Aug. 19, 2021

(54) ELECTRONIC DEVICE AND METHOD FOR MANUFACTURING FLEXIBLE CIRCUIT BOARD

(71) Applicant: Innolux Corporation, Miao-Li County (TW)

(72) Inventors: Jia Sin Li, Miao-Li County (TW); Tong-Jung Wang, Miao-Li County (TW); Chia-Chieh Fan, Miao-Li County (TW); Shan Shan Hsu, Miao-Li County (TW); Chih Han Ma, Miao-Li County (TW)

(73) Assignee: Innolux Corporation, Miao-Li County (TW)

(21) Appl. No.: 17/155,097

(22) Filed: Jan. 22, 2021

(30) Foreign Application Priority Data
Feb. 13, 2020 (CN) 202010091145.2
Jun. 23, 2020 (CN) 202010578733.9

(51) Int. Cl. H05K 1/02; H05K 3/46; H05K 3/00

(52) U.S. Cl. CPC H05K 1/0298; H05K 3/007; H05K 3/467; H05K 1/028

(57) ABSTRACT

An electronic device and a method for manufacturing a flexible circuit board are provided. The electronic device includes the flexible circuit board. The flexible circuit board includes a first flexible substrate, a first seed layer, a first conductive layer, and a second seed layer. The first seed layer is disposed on the first flexible substrate. The first conductive layer is disposed on the first seed layer. The second seed layer is disposed on the first conductive layer. The first seed layer is in contact with the first conductive layer.

### CROSS-REFERENCE TO RELATED APPLICATION

This application claims the priority benefit of China application no. 202010091145.2, filed on Feb. 13, 2020, and China application no. 202010578733.9, filed on Jun. 23, 2020. The entirety of each of the above-mentioned patent applications is hereby incorporated by reference herein and made a part of this specification.

### BACKGROUND

### Technical Field

The disclosure relates to an electronic device and a method for manufacturing a flexible circuit board.

### Description of Related Art

Conventional flexible circuit board is formed by bonding flexible boards formed with copper foils together, and then conducting different layers of the copper foils through a process such as mechanical drilling or laser drilling, etc. Although such manufacturing method is mature, it is still hard to meet the needs of circuit miniaturization or thickness reduction.

### SUMMARY

The disclosure is directed to an electronic device and a method for manufacturing a flexible circuit board, which meet the needs of circuit miniaturization or thickness reduction.

According to an embodiment of the invention, the electronic device includes a flexible circuit board. The flexible circuit board includes a first flexible substrate, a first seed layer, a first conductive layer, and a second seed layer. The first seed layer is disposed on the first flexible substrate. The first conductive layer is disposed on the first seed layer. The second seed layer is disposed on the first conductive layer. The first seed layer is in contact with the first conductive layer.

According to an embodiment of the invention, the method for manufacturing the flexible circuit board includes following steps. A non-flexible substrate is provided. A first seed layer is disposed on the non-flexible substrate. A first conductive layer is disposed on the first seed layer. A second seed layer is disposed on the first conductive layer.

Based on the above description, in the embodiments of the disclosure, the flexible circuit board may be manufactured through photolithography, etching, electroplating and other processes. Therefore, compared with the conventional flexible circuit board, the electronic device and the method for manufacturing the flexible circuit board of the disclosure may meet the needs of circuit miniaturization or thickness reduction.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic partial cross-sectional view of an electronic device according to an embodiment of the disclosure.

FIG. 2A to FIG. 2D are schematic partial cross-sectional views of a manufacturing process of an electronic device according to an embodiment of the disclosure.

FIG. 2D′ and FIG. 2D″ are schematic partial cross-sectional views of electronic devices according to other embodiments of the disclosure.

FIG. 3 is a schematic partial cross-sectional view of an electronic device according to another embodiment of the disclosure.

FIG. 4A to FIG. 4D are schematic partial cross-sectional views of a manufacturing process of an electronic device according to another embodiment of the disclosure.

FIG. 4D′ and FIG. 4D″ are schematic partial cross-sectional views of electronic devices according to other embodiments of the disclosure.

FIG. 5 is a schematic partial cross-sectional view of an electronic device according to another embodiment of the disclosure.

FIG. 5′ is a schematic partial cross-sectional view of an electronic device according to another embodiment of the disclosure.

### DESCRIPTION OF THE EMBODIMENTS

The disclosure may be understood by referring to the following detailed description with reference of the accompanying drawings. It should be noted that, in order to facilitate the reader's understanding and the conciseness of the drawings, the multiple drawings in the disclosure only depict a part of an electronic device, and specific elements in the drawings are not drawn according to actual scales. In addition, the number and size of each element in the figures are only for illustration, and are not used to limit the scope of the disclosure. For example, for clarity's sake, relative size, thickness and position of each film layer, region and/or structure may be reduced or enlarged.

Throughout the specification and claims of the disclosure, certain words are used to refer to specific elements. Those skilled in the art should understand that electronic device manufacturers may refer to the same elements by different names. This specification does not intend to distinguish those elements with the same function but different names. In the following description and claims, the words “have” and “include” are open-ended words, so they should be interpreted as “including but not limited to . . . ”.

Directional terminology used in the specification, such as “top,” “bottom,” “front,” “back,” “left,” “right,” etc., is used with reference to the orientation of the Figure(s) being described. Therefore, the used directional terms are used to illustrate, not to limit the disclosure. It should be understood that when an element or film layer is referred to as being “on” or “connected” to another element or film layer, the element or film layer may be directly on the other element or film layer, or directly connected to the other element or film layer, or there is an intervening element or film layer there between (an indirect situation). Conversely, when an element or film layer is referred to be “directly” on or “directly connected” to another element or film layer, there is no intervening element or film layer there between.

Terms related to bonding and connecting mentioned in the specification, such as “connected”, “interconnected”, etc., unless specifically defined, may mean that two structures are in contact with each other, or that two structures are not in contact with each other, but there are other structures located between the above two structures. The terms of bonding and connecting may also include a situation that both structures are movable or both structures are fixed. In addition, the terms “electrical connection” and “coupling” include any direct and indirect electrical connection means.

The terms “about”, “substantially” or “approximately” mentioned herein generally represent falling within 10% of a given value or range, or represent falling within 5%, 3%, 2%, 1% or 0.5% of the given value or range. In addition, the terms “the given range is from a first value to a second value” and “the given range falls within the range of the first value to the second value” mean that the given range includes the first value, the second value and other values between the first value and the second value.

The terms “first” and “second” mentioned in the specification or claims are only used to name discrete elements or to distinguish different embodiments or ranges, and are not used to limit an upper limit or a lower limit of the number of the elements, and are not used to limit a manufacturing sequence or an arrangement sequence of the elements.

An electronic device may include a display device, an antenna device, a sensing device, a touch display, a curved display, or a free shape display, but the disclosure is not limited thereto. The electronic device may be a bendable or flexible electronic device. The electronic device may include, for example, liquid crystal, light-emitting diodes, fluorescence, phosphor, other suitable display media, or a combination thereof, but the disclosure is not limited thereto. The light-emitting diodes may include, for example, organic light-emitting diodes (OLEDs), mini LEDs, micro LEDs or quantum dot (QD) LEDs (QLEDs, or QDLEDs), or other suitable materials or any arrangement and combination of the above materials, but the disclosure is not limited thereto. The display device may include, for example, a tiling display device, but the disclosure is not limited thereto. The antenna device may be, for example, a liquid crystal antenna, but the disclosure is not limited thereto. The antenna device may include, for example, a tiling antenna device, but the disclosure is not limited thereto. It should be noted that the electronic device may be any arrangement and combination of the foregoing, but the disclosure is not limited thereto. In addition, an appearance of the electronic device may be a rectangle, a circle, a polygon, a shape with curved edges, or other suitable shapes. The electronic device may have peripheral systems such as a driving system, a control system, a light source system, a rack system, etc., to support the display device, the antenna device or the tiling device. Hereinafter, the display device is used as the electronic device to describe the content of the disclosure, but the disclosure is not limited thereto.

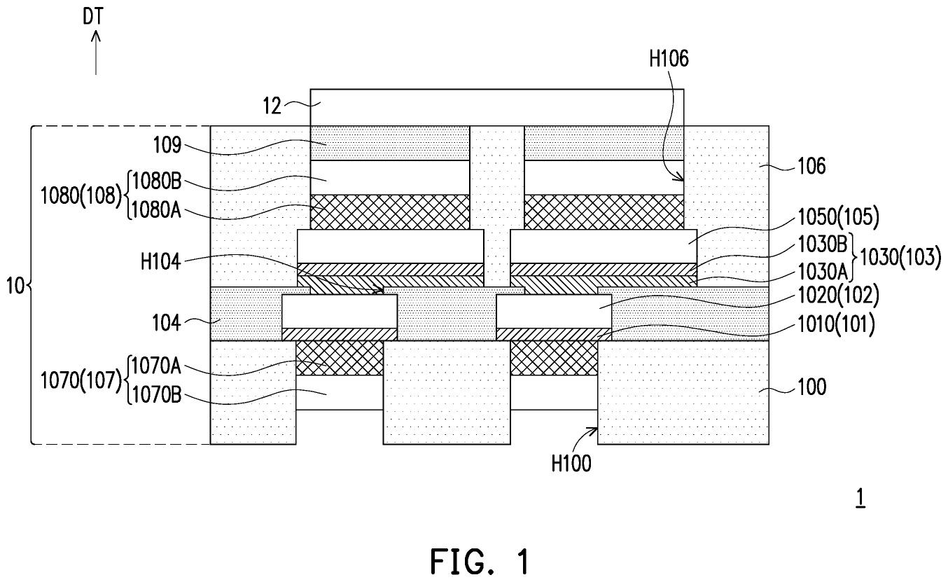

FIG. 1 is a schematic partial cross-sectional view of an electronic device according to an embodiment of the disclosure. Referring to FIG. 1, the electronic device 1 includes a flexible circuit board 10. The flexible circuit board 10 includes a first flexible substrate 100, a first seed layer 101, a first conductive layer 102 and a second seed layer 103. The first seed layer 101 is disposed on the first flexible substrate 100. The first conductive layer 102 is disposed on the first seed layer 101, and the first seed layer 101 is in contact with the first conductive layer 102. The second seed layer 103 is disposed on the first conductive layer 102.

The first flexible substrate 100 may be a thin film substrate or a substrate formed through colloid curing. For example, a material of the first flexible substrate 100 may include polyimide (PI), polyethylene terephthalate (PET) or epoxy (epoxy), but the disclosure is not limited thereto. The first seed layer 101 may be a single-layer seed layer. For example, a material of the first seed layer 101 may include copper (Cu), but the disclosure is not limited thereto. The first conductive layer 102 may comprise the same material as the first seed layer 101, i.e., the material of the first conductive layer 102 may include copper, but the disclosure is not limited thereto. The second seed layer 103 may be a single-layer seed layer or a multi-layer seed layer. Taking the single-layer seed layer as an example, the material of the second seed layer 103 may include nickel chromium (NiCr) alloy or titanium nitride (TiN), but the disclosure is not limited thereto. Taking a multi-layer seed layer as an example, the second seed layer 103 may include a seed bottom layer 1030A and a seed top layer 1030B, where the seed bottom layer 1030A is disposed on the first conductive layer 102 and is in contact with the first conductive layer 102, the seed top layer 1030B is disposed on the seed bottom layer 1030A and is in contact with the seed bottom layer 1030A. The seed top layer 1030B, the first seed layer 101, and the first conductive layer 102 may comprise the same material, and the seed top layer 1030B and the seed bottom layer 1030A may comprise different materials. For example, a material of the seed top layer 1030B may include copper, and a material of the seed bottom layer 1030A may include titanium (Ti) or chromium (Cr), but the disclosure is not limited thereto. In other embodiments, the multi-layer seed layer in the first seed layer 101 or the second seed layer 103 may also be three or more layers. For example, there may be more than one seed layer between the seed top layer and the seed bottom layer.

The first conductive layer 102 is a patterned conductive layer, and the first conductive layer 102 includes a circuit composed of a plurality of wires 1020. The first seed layer 101 is a patterned seed layer and includes a plurality of patterns 1010 overlapped with the wires 1020 in a normal direction DT of the first flexible substrate 100. The first flexible substrate 100 has a plurality of openings H100 exposing the first seed layer 101. The openings H100 are at least partially overlapped with the patterns 1010 of the first seed layer 101 in the normal direction DT of the first flexible substrate 100, so that the first seed layer 101 may be connected with another element (which is described later).

According to different requirements, the flexible circuit board 10 may also include other elements. For example, the flexible circuit board 10 may further include an insulating layer 104. The insulating layer 104 is disposed on the first flexible substrate 100 and the first conductive layer 102. For example, a material of the insulating layer 104 may include polyimide, polybenzoxazole (PBO), benzocyclobutene (BCB), tetrafluoroethylene-perfluoroalkyl vinyl ether copolymer (Polyfluoroalkoxy, PFA), silicon nitride (SiNx), silicon oxide (SiOx), silicon oxynitride (SiOxNy) or other photosensitive insulating materials.

The insulating layer 104 may have a plurality of openings H104 exposing the first conductive layer 102. The second seed layer 103 is disposed on the insulating layer 104 and is in contact with the first conductive layer 102 through the openings H104. For example, the openings H104 are at least partially overlapped with the wires 1020 of the first conductive layer 102 in the normal direction DT of the first flexible substrate 100, so that the seed bottom layer 1030A of the second seed layer 103 disposed on the insulating layer 104 may contact the wires 1020 of the first conductive layer 102 through the openings H104.

The flexible circuit board 10 may further include a second conductive layer 105 and a second flexible substrate 106. The second conductive layer 105 is disposed on the second seed layer 103. The second conductive layer 105 may comprise the same material as the second seed layer 103. For example, the material of the second conductive layer 105 may include copper, but the disclosure is not limited thereto. The second flexible substrate 106 is disposed on the insulating layer 104 and the second conductive layer 105. Regarding the type or material of the second flexible substrate 106, reference may be made to the description of the first flexible substrate 100, and detail thereof is not repeated.

The second conductive layer 105 is a patterned conductive layer, and the second conductive layer 105 includes a circuit composed of a plurality of wires 1050. The second seed layer 103 is a patterned seed layer and includes a plurality of patterns 1030 overlapped with the wires 1050 in the normal direction DT of the first flexible substrate 100. The second flexible substrate 106 has a plurality of openings H106 exposing the second conductive layer 105. The openings H106 are at least partially overlapped with the wires 1050 of the second conductive layer 105 in the normal direction DT of the first flexible substrate 100, so that the second conductive layer 105 may be connected to another element (which is described later).

The flexible circuit board 10 may further include a conductive pad layer 107, a conductive pad layer 108, and conductive bumps 109. The conductive pad layer 107 may be a single-layer metal layer or a multi-layer metal layer. Taking the single-layer metal layer as an example, a material of the conductive pad layer 107 may include palladium-gold alloy, tin (Sn), silver (Ag), nickel-gold alloy or organic surface protection (organic surface protection, OSP). Taking the multi-layer metal layer as an example, the conductive pad layer 107 may include a conductive pad bottom layer 1070A and a conductive pad top layer 1070B. A material of the conductive pad bottom layer 1070A may include nickel or nickel-palladium alloy, but the disclosure is not limited thereto. A material of the conductive pad top layer 1070B may include gold, but the disclosure is not limited thereto. The conductive pad layer 108 may be a single-layer metal layer or a multi-layer metal layer. The above description may be referred for description of the single-layer metal layer, which is not repeated. Taking the multi-layer metal layer as an example, the conductive pad layer 108 may include a conductive pad bottom layer 1080A and a conductive pad top layer 1080B. Materials of the conductive pad bottom layer 1080A and the conductive pad top layer 1080B may refer to the related description of the conductive pad bottom layer 1070A and the conductive pad top layer 1070B, which are not repeated. In other embodiments, the multi-layer metal layer in the conductive pad layer 107 or the conductive pad layer 108 may also be three or more layers. A material of the conductive bumps 109 may include tin, but the disclosure is not limited thereto.

The conductive pad layer 107 may include a plurality of pad patterns 1070. The pad patterns 1070 are disposed in the openings H100 of the first flexible substrate 100 and are in contact with the patterns 1010 exposed by the openings H100. The conductive pad bottom layer 1070A is located between the conductive pad top layer 1070B and the first seed layer 101. The conductive pad layer 108 may include a plurality of pad patterns 1080. The pad patterns 1080 are disposed in the openings H106 of the second flexible substrate 106 and are in contact with the wires 1050 exposed by the openings H106. The conductive pad bottom layer 1080A is located between the conductive pad top layer 1080B and the second conductive layer 105. The conductive bumps 109 are disposed on the conductive pad layer 108 and are in contact with the conductive pad layer 108.

The electronic device 1 may further include at least one element 12. The at least one element 12 may be electrically connected to the conductive pad layer 108 in the flexible circuit board 10 through the conductive bumps 109. The at least one element 12 may include a resistor, a capacitor, an inductor, a diode, a transistor, an integrated circuit (IC), etc., but the disclosure is not limited thereto. In some embodiments, the elements may be electrically connected to each other.

It should be understood that the thickness, width or number of each film layer or element or the relative arrangement relationship or connection relationship between multiple elements in FIG. 1 are only for illustration, not for limitation. In other embodiments, any of the above parameters may be changed according to actual requirements. For example, a line width, a line pitch, or a layout method of the wires in any conductive layer (or referred to as a metal circuit layer) of the flexible circuit board 10 may be changed according to actual requirements. The flexible circuit board 10 may also be configured with more than two layers of metal circuit layers and an insulating layer used for separating the two top and bottom metal circuit layers adjacent to each other. The electronic device 1 may further include an additional element, and the additional element may be electrically connected to the at least one element 12 or an external device through the flexible circuit board 10. The additional element may include a display element, an antenna element, a sensing element or a light-emitting element, but the disclosure is not limited thereto.

In the following embodiments, the same or similar elements may be denoted by the same or similar reference numerals, and descriptions thereof are omitted. In addition, the features in different embodiments may be mixed and matched arbitrarily as long as they do not violate the spirit of the invention or there is no confliction, and simple equivalent changes and modifications made in accordance with this specification or claims still fall within the scope of the disclosure.

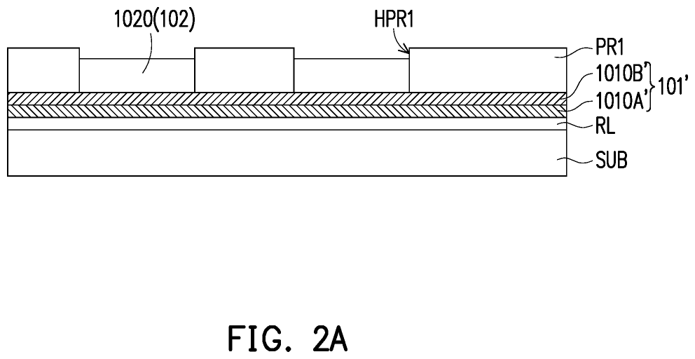

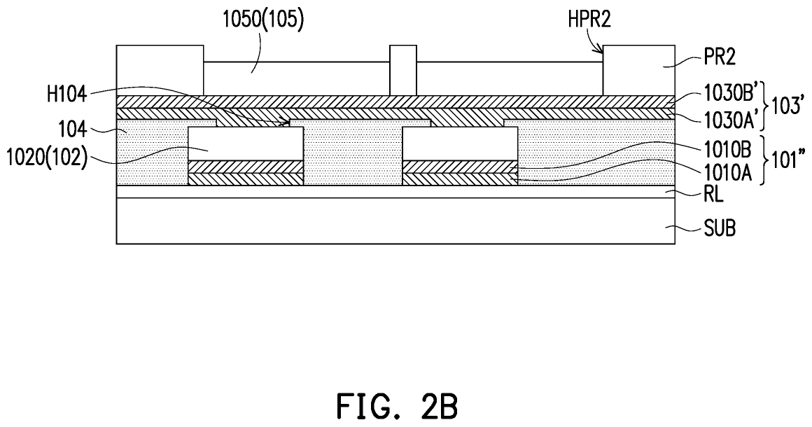

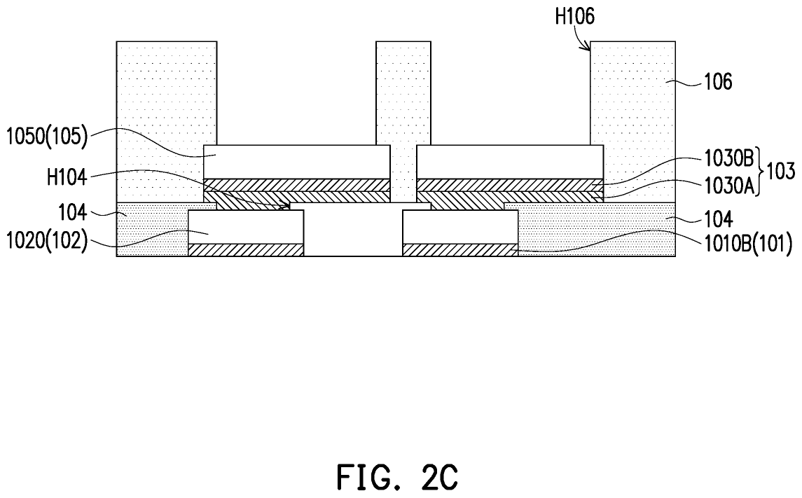

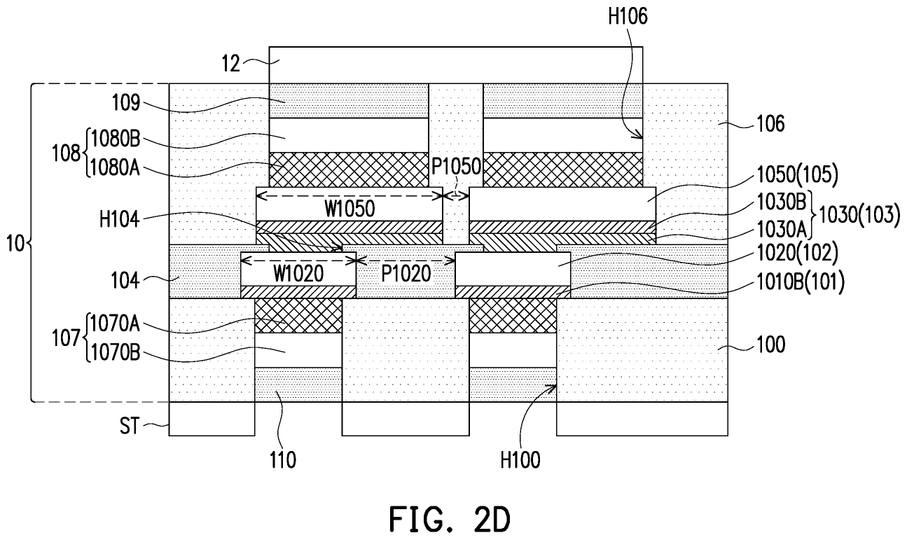

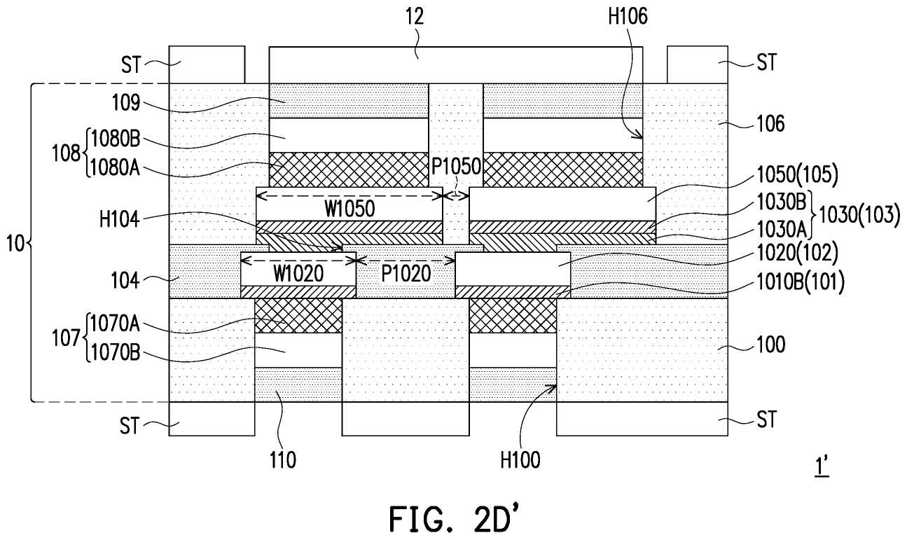

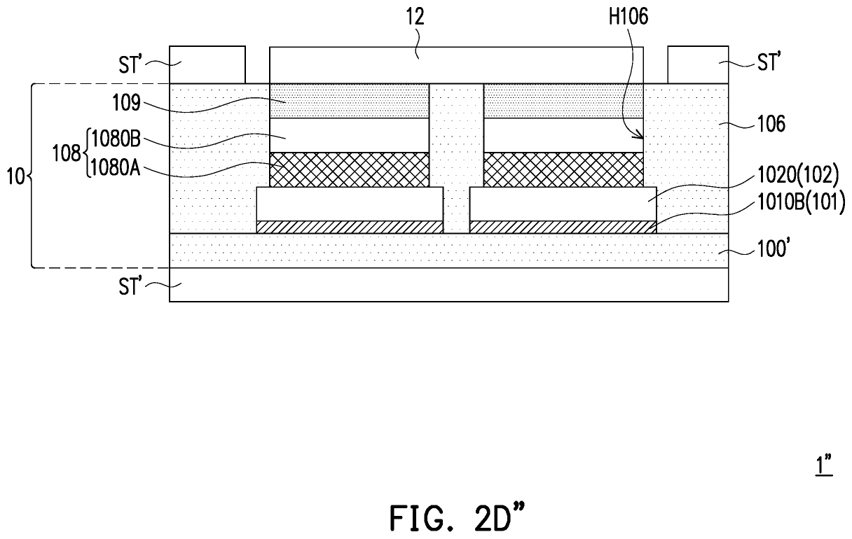

FIG. 2A to FIG. 2D are schematic partial cross-sectional views of a manufacturing process of an electronic device according to an embodiment of the disclosure. The manufacturing process of the flexible circuit board 10 of the electronic device 1 in FIG. 1 is shown with reference to FIG. 2A to FIG. 2D, but the disclosure is not limited thereto.

Referring to FIG. 2A, a non-flexible substrate SUB is provided. The non-flexible substrate SUB has a certain degree of supportiveness or rigidity. For example, the non-flexible substrate SUB may be a glass substrate or other hard substrates.

Then, a peeling layer RL is disposed on the non-flexible substrate SUB. For example, a coating process and a curing process may be sequentially applied to form the peeling layer RL. The peeling layer RL may have adhesiveness, and the peeling layer RL may lose its adhesiveness under a function of light or heat. For example, a material of the peeling layer RL may include silica gel, and the peeling layer RL may lose adhesiveness through a laser lift-off (LLO) process, but the disclosure is not limited thereto.

Then, a first seed layer 101′ is disposed on the peeling layer RL. For example, a seed bottom layer 1010A′ and a seed top layer 1010B′ may be sequentially formed on the peeling layer RL through a sputtering process. Materials of the seed bottom layer 1010A′ and the seed top layer 1010B′ may refer to the materials of the aforementioned seed bottom layer 1030A and the seed top layer 1030B, which are not repeated.

Then, a photoresist layer PR1 is disposed on the first seed layer 101′. The photoresist layer PR1 is a patterned photoresist layer and has openings HPR1. For example, the photoresist layer PR1 may be formed on the first seed layer 101′ by sequentially applying a photolithography process and an etching process. The photolithography process includes sequentially applying processing procedures of coating, prebaking, exposing, developing, postbaking, etc.

Then, the first conductive layer 102 is disposed in the openings HPR1 of the photoresist layer PR1. For example, the first conductive layer 102 may be formed in the openings HPR1 through an electroplating process.

Referring to FIG. 2B, the photoresist layer PR1 is removed. For example, the photoresist layer PR1 may be removed by an ashing process or a wet stripping process, but the disclosure is not limited thereto.

Then, the first seed layer 101′ that is not covered by the first conductive layer 102 is removed. For example, the first conductive layer 102 may be used as a mask to remove the first seed layer 101′ that is not covered by the first conductive layer 102 in FIG. 2A through an etching process, so as to form a first seed layer 101″. A difference between the first seed layer 101″ and the first seed layer 101′ is that the first seed layer 101′ (including the seed bottom layer 1010A′ and the seed top layer 1010B′) is a continuous thin film, and the first seed layer 101″ (including a seed bottom layer 1010A and a seed top layer 1010B) is a patterned film layer. Since the first seed layer 101″ is formed through an etching process by using the first conductive layer 102 as a mask, an orthographic projection of the first seed layer 101″ on the non-flexible substrate SUB is equal to or similar to an orthographic projection of the first conductive layer 102 on the non-flexible substrate SUB.

Then, the insulating layer 104 is disposed on the first conductive layer 102 and the peeling layer RL. For example, the insulating layer 104 may be formed by sequentially applying a photolithography process and an etching process.

Then, a second seed layer 103′ is disposed on the first conductive layer 102 and the insulating layer 104. For example, a sputtering process may be applied to sequentially form a seed bottom layer 1030A′ and a seed top layer 1030B′ on the first conductive layer 102 and the insulating layer 104. Materials of the seed bottom layer 1030A′ and the seed top layer 1030B′ may refer to the materials of the aforementioned seed bottom layer 1030A and the seed top layer 1030B, which are not repeated.

Then, a photoresist layer PR2 is disposed on the second seed layer 103′. The photoresist layer PR2 is a patterned photoresist layer and has openings HPR2. The method of manufacturing the photoresist layer PR2 may refer to related description of the photoresist layer PR1, which is be repeated.

Then, the second conductive layer 105 is disposed in the openings HPR2 of the photoresist layer PR2. For example, an electroplating process may be applied to form the second conductive layer 105 in the openings HPR2.

Referring to FIG. 2C, the photoresist layer PR2 is removed. For example, the photoresist layer PR2 may be removed by an ashing process or a wet stripping process, but the disclosure is not limited thereto.

Then, the second seed layer 103′ that is not covered by the second conductive layer 105 is removed. For example, the second conductive layer 105 may be used as a mask to remove the second seed layer 103′ that is not covered by the second conductive layer 105 in FIG. 2B through an etching process, so as to form the second seed layer 103. A difference between the second seed layer 103 and the second seed layer 103′ is that the second seed layer 103′ (including the seed bottom layer 1030A′ and the seed top layer 1030B′) is a continuous thin film, while the second seed layer 103 (including the seed bottom layer 1030A and the seed top layer 1030B) is a patterned film layer. Since the second seed layer 103 is formed through an etching process by using the second conductive layer 105 as a mask, areas of the second seed layer 103 and the second conductive layer 105 are substantially the same in a top view direction. According to the aforementioned steps, a first metal circuit layer and a second metal circuit layer in the flexible circuit board may be formed. According to the required number of layers, the aforementioned steps of forming the insulating layer, the seed layer, and the conductive layer may be repeated by one or more times after forming the second seed layer 103, so as to further form one layer or more layers of metal circuit layers. Two top and bottom metal circuit layers adjacent to each other may be separated by an insulating layer. The openings of each insulating layer expose the metal circuit layer located under and in contact with the insulating layer. A distribution of the openings of the insulating layers may be designed according to actual requirements. For example, the openings of the insulating layers may be misaligned with each other to form blind holes; or the openings of the insulating layers may be overlapped in the normal direction DT (referring to FIG. 1) of the first flexible substrate 100 (referring to FIG. 1) to form through holes.

After fabrication of the required metal circuit layers is completed, the second flexible substrate 106 may be disposed on the insulating layer 104 and the second conductive layer 105 (the uppermost insulating layer and metal circuit layer). For example, the second flexible substrate 106 may be formed on the insulating layer 104 and the second conductive layer 105 by sequentially applying a coating or printing process (such as screen printing) and a curing process. Alternatively, the second flexible substrate 106 may be formed on the insulating layer 104 and the second conductive layer 105 by sequentially applying a coating or printing process, a curing process, a photolithography process, and an etching process. Alternatively, the openings H106 may be formed on the thin film substrate (not shown) through punching, and then the thin film substrate having the openings H106 may be attached to the insulating layer 104 through an adhesive layer (not shown). Alternatively, the thin film substrate (not shown) may be attached to the insulating layer 104 through the adhesive layer (not shown), and then the openings H106 are formed through a photolithography process and an etching process. In the first two manufacturing methods, the second flexible substrate 106 is in contact with the insulating layer 104, and the adhesive layer there between may be omitted. In the latter two manufacturing methods, there is an adhesive layer (not shown) between the second flexible substrate 106 and the insulating layer 104. Alternatively, a photo-imageable coverlay (PIC) may be pressed on the insulating layer 104 and the second conductive layer 105 by using a vacuum air bag hot press, and then the second flexible substrate 106 with the openings H106 may be formed through processes such as baking and drying, exposure and development, etc. Compared with using a photo solder resistance (PSR) ink to form the second flexible substrate 106, to use the photo-imageable coverlay to produce the second flexible substrate 106 may reduce an overall thickness, or reduce the common problems such as plugging, uneven thickness or long standing time occurred in screen printing. In addition, the photo-imageable coverlay has a low solvent content, so that a problem of poor odor is mitigated to meet environmental protection regulations. Moreover, the photo-imageable coverlay has good flexibility and may provide a circuit protection effect.

Then, the peeling layer RL and the non-flexible substrate SUB are removed. For example, a laser lift-off process may be applied to separate the peeling layer RL and the non-flexible substrate SUB from the insulating layer 104 and the first seed layer 101″.

Then, an etching process (such as a wet etching process or a dry etching process) may be applied to remove at least a part of the first seed layer 101″. Taking the first seed layer 101″ including the seed bottom layer 1010A and the seed top layer 1010B as an example, since the existence of the seed bottom layer 1010A (referring to FIG. 2B) may cause difficulties in subsequent formation of the conductive pad layer 107, the seed bottom layer 1010A may be removed through an etching process to expose the seed top layer 1010B and form the first seed layer 101 shown in FIG. 1. A difference between the first seed layer 101 and the first seed layer 101″ is that the first seed layer 101 does not include the seed bottom layer 1010A. In another embodiment, when the first seed layer 101″ is a single-layer seed layer (such as nickel-chromium alloy or titanium nitride), the first seed layer 101″ may be entirely removed by an etching process to expose the first conductive layer 102.

Referring to FIG. 2D, the first flexible substrate 100 is formed under the seed top layer 1010B and the insulating layer 104. The openings H100 of the first flexible substrate 100 expose the seed top layer 1010B of the first seed layer 101, and the seed top layer 1010B of the first seed layer 101 and the first conductive layer 102 are located in the first flexible substrate 100 and the second flexible substrate 106, and the second seed layer 103, the second conductive layer 105 and the insulating layer 104 may be located in the first flexible substrate 100 or the second flexible substrate 106. The method of forming the first flexible substrate 100 may refer to the related description of the second flexible substrate 106, which is not repeated.

Then, the conductive pad layer 107 is disposed in the openings H100 of the first flexible substrate 100, and the conductive pad layer 108 is disposed in the openings H106 of the second flexible substrate 106. The method of forming the conductive pad layer 107 and the conductive pad layer 108 may include electroless nickel immersion gold (ENIG), electroless nickel electroless palladium immersion gold (ENEPIG), electroless palladium autocatalytic gold (EPAG), immersion tin (ISn), immersion silver (IAg), nickel-gold electroplating, lead-free hot-air solder levelling (HASL) or OSP (organic solder protection film), but the disclosure is not limited thereto. For illustrative purposes, FIG. 2D shows the conductive pad layer 107 and the conductive pad layer 108 formed by the electroless nickel immersion gold method. In other embodiments, based on the different manufacturing methods, the conductive pad layer 107 and the conductive pad layer 108 may be single-layer metal layers or multi-layer metal layers. In addition, according to different design requirements, the conductive pad layer 107 and the conductive pad layer 108 may be fabricated together or separately.

Referring to FIG. 2D, the conductive bumps 109 and the elements 12 are sequentially disposed on the conductive pad layer 108 by using a surface mounting technology (SMT). In this way, the flexible circuit board 10 of the electronic device 1 shown in FIG. 1 is initially completed.

In an embodiment, before the conductive bumps 109 and the elements 12 are configured, the first flexible substrate 100 may be fixed to an auxiliary substrate ST first. For example, the first flexible substrate 100 may be fixed to the auxiliary substrate ST by a lamination process. The auxiliary substrate ST, for example, has supportiveness or rigidity and is suitable for carrying the flexible circuit board 10. For example, the auxiliary substrate ST may be a glass substrate or other hard substrates. Alternatively, the auxiliary substrate ST may be a polyimide (PI) substrate or other substrates with stiffness. In addition, when the conductive bumps 109 are provided or after the conductive bumps 109 and the elements 12 are provided, conductive bumps 110 may be selectively disposed on the conductive pad layer 107. A material of the conductive bumps 110 may, for example, include tin, but the disclosure is not limited thereto.

By combining the auxiliary substrate ST with stiffness and the second flexible substrate 106 with flexibility, an overall stiffness of the flexible circuit board 10 may be improved, which helps to improve a bonding yield of the flexible circuit board 10 and the elements 12.

By using the processes such as photolithography, etching, and electroplating to fabricate the film layers in the flexible circuit board, the electronic device and the method for manufacturing the flexible circuit board may meet the needs of circuit miniaturization or thickness reduction. For example, a thickness of the seed layer (such as the first seed layer 101 or the second seed layer 103) may be greater than 0 μm and less than or equal to 1 μm. A thickness of the conductive layer (such as the first conductive layer 102 or the second conductive layer 105) may be greater than or equal to 0.5 μm and less than or equal to 25 μm. For example, the thickness of the conductive layer may be greater than or equal to 0.5 μm and less than or equal to 20 μm, greater than or equal to 0.5 μm and less than or equal to 15 μm, greater than or equal to 0.5 μm and less than or equal to 10 μm, greater than or equal to 0.5 μm and less than or equal to 5 μm. A thickness of the insulating layer (such as the insulating layer 104) may be greater than 1 μm and less than or equal to 50 μm. For example, the thickness of the insulating layer may be greater than 1 μm and less than or equal to 40 μm, greater than 1 μm and less than or equal to 30 μm, greater than 1 μm and less than or equal to 20 μm, greater than 1 μm and less than or equal to 10 μm. A line width of the wires in the conductive layer (for example, a line width W1020 of the wires 1020 or a line width W1050 of the wires 1050) may be greater than or equal to 2 μm. A line pitch of the wires in the conductive layer (such as a line pitch P1020 or a line pitch P1050) may be greater than or equal to 2 μm.

It should be understood that although the first seed layer 101 and the first conductive layer 102 may be made of the same material (i.e., the first seed layer 101 and the first conductive layer 102 may comprise the same material, such as copper), since the first seed layer 101 is formed by a sputtering process, and the first conductive layer 102 is formed by an electroplating process, a grain size of the first seed layer 101 may be smaller than a grain size of the first conductive layer 102. Therefore, there is an interface between the first seed layer 101 and the first conductive layer 102, and such interface may be viewed through a microscope (such as a scanning electron microscope (SEM)). Similarly, the seed top layer 1030B of the second seed layer 103 and the second conductive layer 105 may be made of the same material (i.e., the seed top layer 1030B of the second seed layer 103 and the second conductive layer 105 may comprise the same material, such as copper), but since the seed top layer 1030B is formed by a sputtering process, and the second conductive layer 105 is formed by an electroplating process, a grain size of the seed top layer 1030B may be smaller than a grain size of the second conductive layer 105.

FIG. 2D′ and FIG. 2D″ are schematic partial cross-sectional views of electronic devices according to other embodiments of the disclosure. Referring to FIG. 2D′, differences between an electronic device 1′ and the electronic device of FIG. 2D are as follows.

In the electronic device 1′, besides that the auxiliary substrate ST is disposed on the first flexible substrate 100, the auxiliary substrate ST is also disposed on the second flexible substrate 106, and the auxiliary substrate ST disposed on the second flexible substrate 106 may be located on at least one side of the element 12. For example, in a top view direction, the auxiliary substrate ST may be located on three sides of the element 12 in a U-shape. On the other hand, the auxiliary substrate ST disposed on the first flexible substrate 100 not only exposes the two conductive bumps 110, but also exposes the first flexible substrate 100 located between the two conductive bumps 110. In some embodiments, the auxiliary substrate ST disposed on the second flexible substrate 106 may be located at periphery of the element 12.

By disposing the auxiliary substrate ST with stiffness on the first flexible substrate 100 and the second flexible substrate 106, the overall stiffness of the flexible circuit board 10 may be further improved, which helps to further improve the bonding yield of the flexible circuit board 10 and the elements 12. In addition, the auxiliary substrate ST may protect (for example, prevent scratching) the first flexible substrate 100 and the second flexible substrate 106, or may improve the convenience of picking up the flexible circuit board 10 during manufacturing or transportation.

Referring to FIG. 2D″, differences between an electronic device 1″ and the electronic device 1′ of FIG. 2D′ are as follows. In the electronic device 1′, the flexible circuit board 10 includes multiple metal circuit layers, such as the first conductive layer 102 and the second conductive layer 105. Comparatively, in the electronic device 1″, the flexible circuit board 10″ includes one metal circuit layer, such as the first conductive layer 102. In addition, the second flexible substrate 106 is disposed on the first flexible substrate 100′ and the first conductive layer 102, and a plurality of openings H106 of the second flexible substrate 106 respectively expose a plurality of wires 1020 of the first conductive layer 102. The conductive pad layer 108 is disposed in the plurality of openings H106 and is in contact with the plurality of wires 1020 of the first conductive layer 102. The first flexible substrate 100′ is, for example, a flexible substrate that does not have the openings H100 (referring to FIG. 2D′). The auxiliary substrate ST′ is disposed on the first flexible substrate 100′ and the second flexible substrate 106, where the auxiliary substrate ST′ disposed on the first flexible substrate 100′ may not have openings. In another embodiment, the first flexible substrate 100′ may be omitted, and the first seed layer 101 and the second flexible substrate 106 may be disposed on the auxiliary substrate ST′. For example, after the first conductive layer 102 in FIG. 2A is formed, the second flexible substrate 106 may be disposed on the first conductive layer 102 and the peeling layer RL, and then the non-flexible substrate SUB, the peeling layer RL and the seed bottom layer 1010A are removed to form the first flexible substrate 100′ (optional) and the auxiliary substrate ST′.

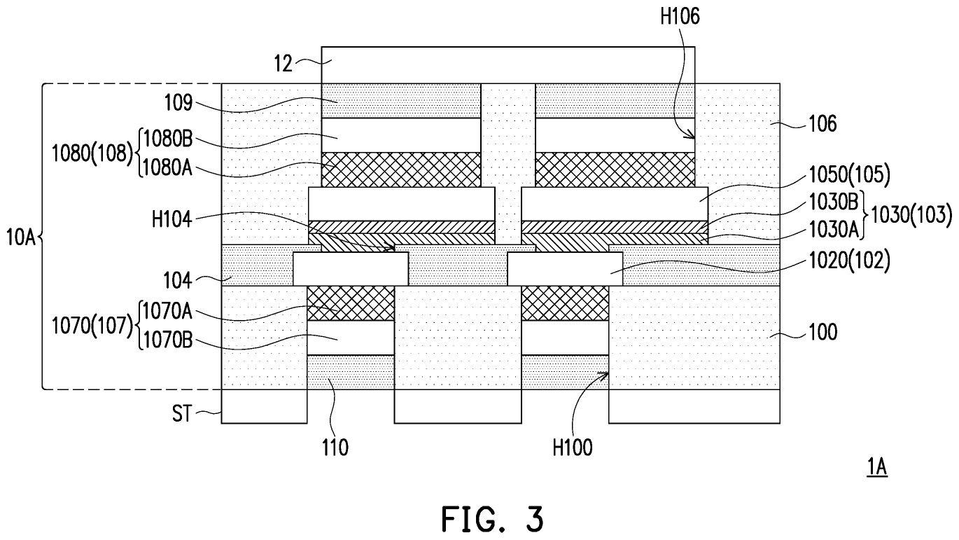

FIG. 3 is a schematic partial cross-sectional view of an electronic device according to another embodiment of the disclosure. Referring to FIG. 3, differences between an electronic device 1A and the electronic device 1 of FIG. 1 are as follows.

In the electronic device 1A, a flexible circuit board 10A does not include the first seed layer. For example, when the first seed layer is a single-layer seed layer (such as nickel-chromium alloy or titanium nitride), the first seed layer may be entirely removed to expose the first conductive layer 102. Therefore, the first flexible substrate 100 is formed under the first conductive layer 102 and the insulating layer 104, and the conductive pad layer 107 is in contact with the first conductive layer 102.

In other embodiments, FIG. 3 may be replaced with the technical features of FIG. 2D′, (for example, FIG. 3 may be modified by referring to the configuration of the auxiliary substrate ST in FIG. 2D′), or replaced with the technical features of FIG. 2D″ (for example, referring to the number of the metal circuit layers in FIG. 2D″, the arrangement of the second flexible substrate 106, and the design of the first flexible substrate 100′ and the auxiliary substrate ST′).

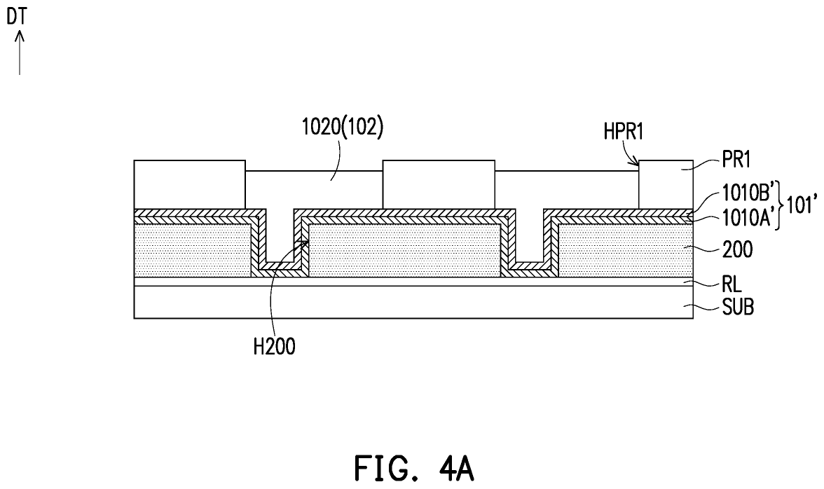

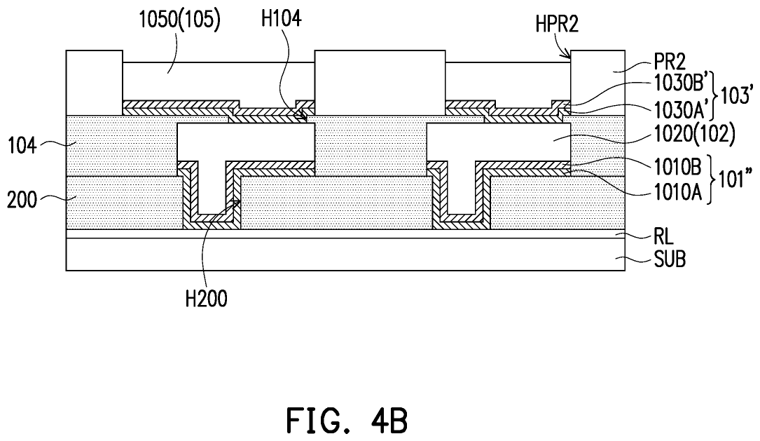

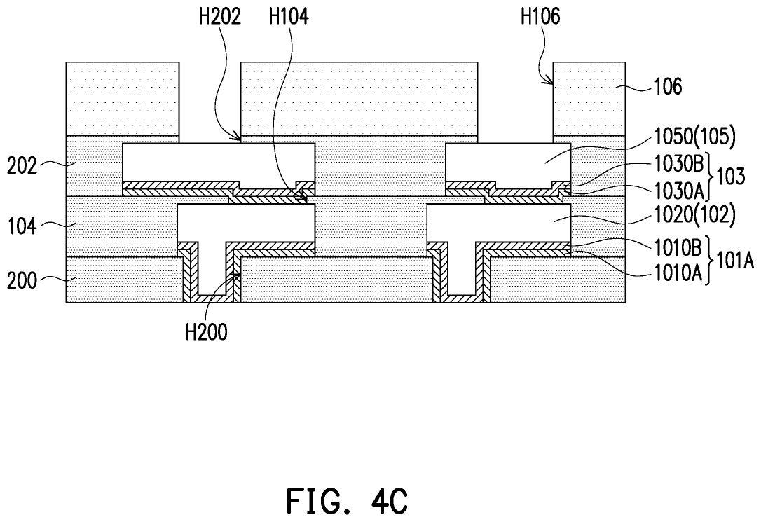

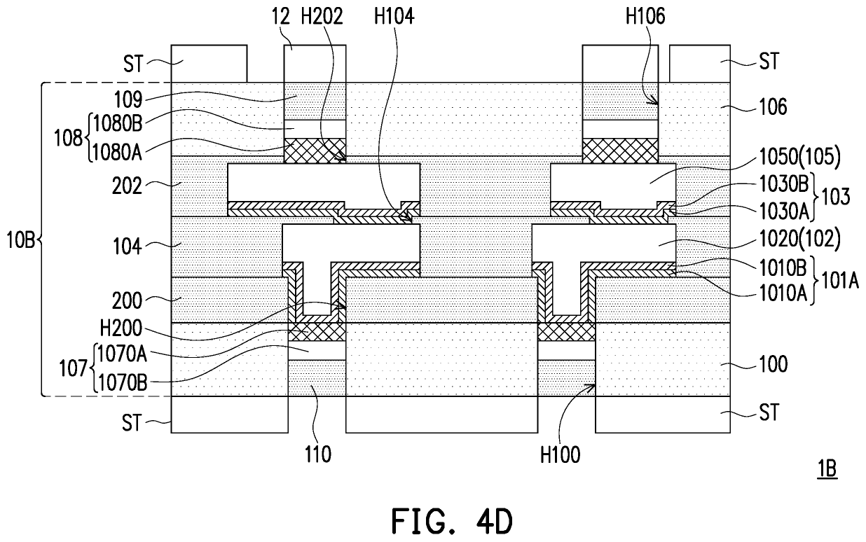

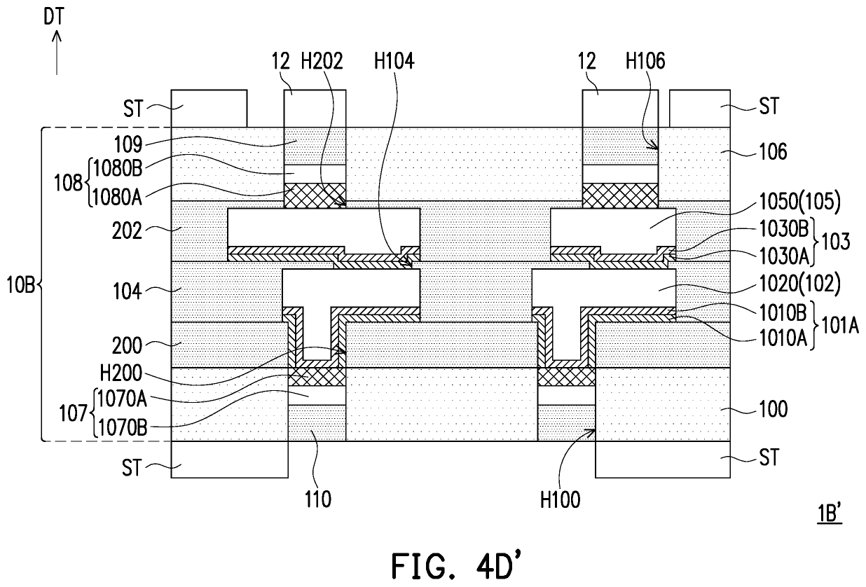

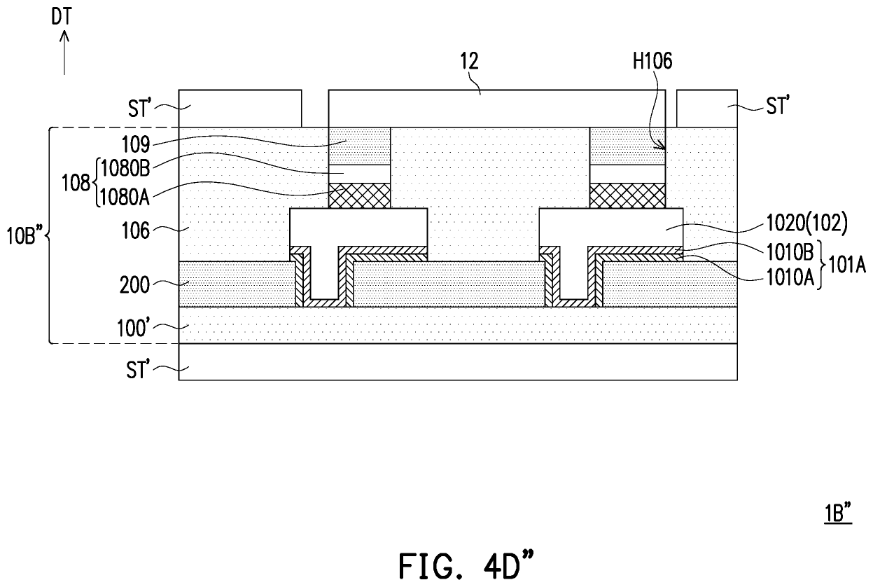

FIG. 4A to FIG. 4D are schematic partial cross-sectional views of a manufacturing process of an electronic device according to another embodiment of the disclosure. The elements in FIG. 4A to FIG. 4D that are the same as or similar to those in FIG. 2A to FIG. 2D may be denoted by the same or similar reference numerals, and descriptions thereof are omitted.

Referring to FIG. 4A, a difference between the step shown in FIG. 4A and the step shown in FIG. 2A is that in FIG. 4A, before the first seed layer 101′ is formed, an insulating layer 200 is first disposed on the peeling layer RL. The insulating layer 200 is a patterned insulating layer and has openings H200 exposing the peeling layer RL. A material and a manufacturing method of the insulating layer 200 may refer to the related description of the insulating layer 104, which are not repeated. After the insulating layer 200 is formed, the first seed layer 101′ is formed on the peeling layer RL and the insulating layer 200, where a part of the first seed layer 101′ is disposed on the peeling layer RL, and the other part of the first seed layer 101′ is located in the openings H200 and contacts the peeling layer RL and sidewalls of the openings H200.

Then, the photoresist layer PR1 is disposed on the first seed layer 101′, where the openings HPR1 of the photoresist layer PR1 are overlapped with the openings H200 in the normal direction DT of the first flexible substrate 100.

Then, the first conductive layer 102 is disposed on the first seed layer 101′. The first conductive layer 102 is filled in the openings HPR1 of the photoresist layer PR1 and is in contact with the first seed layer 101′ in the openings H200.

Referring to FIG. 4B, the photoresist layer PR1 is removed. Then, the first seed layer 101′ not covered by the first conductive layer 102 is removed to form the first seed layer 101″.

Then, the insulating layer 104 is disposed on the insulating layer 200 and the first conductive layer 102.

Then, the second seed layer 103′, the photoresist layer PR2, and the second conductive layer 105 are sequentially disposed on the insulating layer 104 and the first conductive layer 102.

Referring to FIG. 4C, the photoresist layer PR2 is removed. Then, the second seed layer 103′ not covered by the second conductive layer 105 is removed to form the second seed layer 103.

According to the aforementioned steps, the first metal circuit layer and the second metal circuit layer in the flexible circuit board may be formed. According to the required number of layers, the steps of forming the insulating layer, the seed layer, and the conductive layer may be repeated by one or more times after the second seed layer 103 is formed, so as to further form one layer or more layers of metal circuit layers. Two top and bottom metal circuit layers adjacent to each other may be separated by an insulating layer. The openings of each insulating layer expose the metal circuit layer located under and in contact with the insulating layer. A distribution of the openings of the insulating layers may be designed according to actual requirements. For example, the openings of the insulating layers may be misaligned with each other to form blind holes; or the openings of the insulating layers may be overlapped in the normal direction DT (referring to FIG. 1) of the first flexible substrate 100 (referring to FIG. 1) to form through holes.

After fabrication of the required metal circuit layers is completed, an insulating layer 202 may be disposed on the insulating layer 104 and the second conductive layer 105 (the uppermost insulating layer and metal circuit layer). The insulating layer 202 is a patterned insulating layer and has openings H202 exposing the second conductive layer 105. The material and manufacturing method of the insulating layer 202 may refer to the related description of the insulating layer 104, which is not repeated. Then, the second flexible substrate 106 is disposed on the insulating layer 202. In an embodiment, the insulating layer 202 may be omitted, and the second flexible substrate 106 is disposed on the insulating layer 104 and the second conductive layer 105 (the uppermost insulating layer and the metal circuit layer).

Then, the peeling layer RL and the non-flexible substrate SUB are removed. Then, at least a part of the first seed layer 101″ in FIG. 4B may be removed by an etching process. For example, the seed bottom layer 1010A exposed after the peeling layer RL and the non-flexible substrate SUB are removed may be removed to expose the seed top layer 1010B and form a first seed layer 101A. The difference between the first seed layer 101A and the first seed layer 101 in FIG. 2C is that the first seed layer 101A includes the seed bottom layer 1010A located between the insulating layer 200 and the seed top layer 1010B.

Referring to FIG. 4D, the first flexible substrate 100 is formed under the seed top layer 1010B and the insulating layer 200. Then, the conductive pad layer 107 is disposed in the openings H100 of the first flexible substrate 100, and the conductive pad layer 108 is disposed in the openings H106 of the second flexible substrate 106.

Then, the first flexible substrate 100 is fixed to the auxiliary substrate ST. Then, the conductive bumps 109 and the elements 12 are sequentially disposed on the conductive pad layer 108. In addition, the conductive bumps 110 may be selectively disposed on the conductive pad layer 107. In this way, fabrication of a flexible circuit board 10B of an electronic device 1B is initially completed.

FIG. 4D′ and FIG. 4D″ are schematic partial cross-sectional views of electronic devices according to other embodiments of the disclosure. An electronic device 1B′ of FIG. 4D′ is obtained by modifying the electronic device 1B of FIG. 4D with reference to the arrangement of the auxiliary substrate ST in FIG. 2D′. An electronic device 1B″ (for example, a flexible circuit board 10B″) of FIG. 4D″ is obtained by modifying the electronic device 1B′ of FIG. 4D′ with reference to the number of the metal circuit layers, the arrangement of the second flexible substrate 106, and the design of the first flexible substrate 100′ and the auxiliary substrate ST′ in FIG. 2D″, and detailed description thereof may refer to the related description of FIG. 2D′ and FIG. 2D″, which is not repeated.

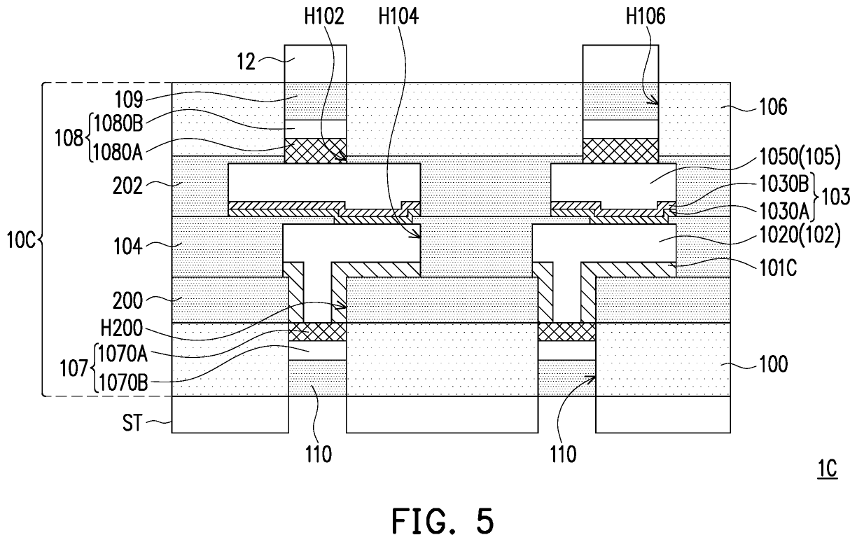

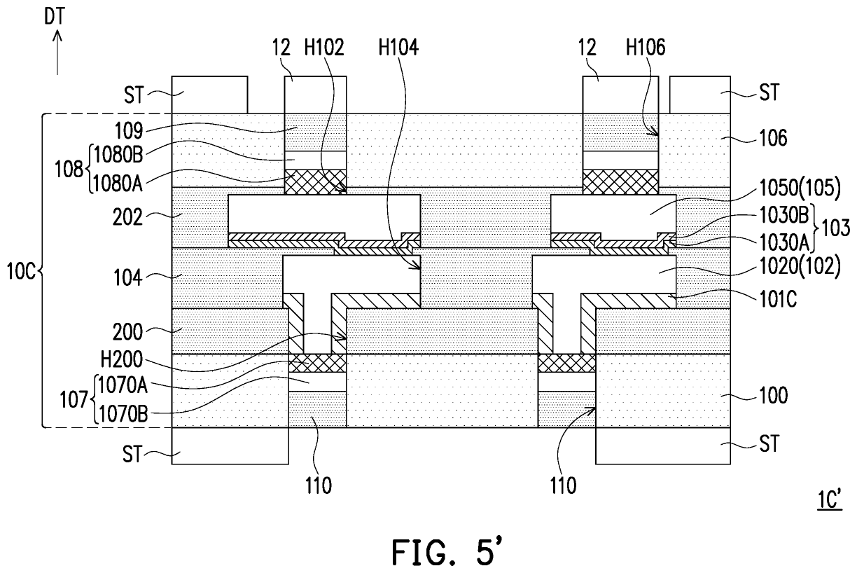

FIG. 5 is a schematic partial cross-sectional view of an electronic device according to another embodiment of the disclosure. Referring to FIG. 5, differences between an electronic device 1C and the electronic device 1B of FIG. 4D are as follows.

In the electronic device 1C, a first seed layer 101C of a flexible circuit board 10C is a single-layer seed layer. In the step of FIG. 4C, the first seed layer 101C exposed after the peeling layer RL and the inflexible substrate SUB are removed is removed to expose the first conductive layer 102. Therefore, in the step of FIG. 4D, the first flexible substrate 100 is formed under the first conductive layer 102 and the insulating layer 200, and the conductive pad layer 107 is in contact with the first conductive layer 102.

FIG. 5′ is a schematic partial cross-sectional view of an electronic device according to another embodiment of the disclosure. An electronic device 1C′ of FIG. 5′ is obtained by modifying the electronic device 1C of FIG. 5 with reference to the arrangement of the auxiliary substrate ST in FIG. 2D′. In another embodiment, the electronic device 1C of FIG. 5 may also be modified with reference to the number of the metal circuit layers, the arrangement of the second flexible substrate 106, and the design of the first flexible substrate 100′ and the auxiliary substrate ST′ in FIG. 2D″, and detailed description thereof may refer to the related description of FIG. 2D′ and FIG. 2D″, which is not repeated.

In summary, in the embodiments of the disclosure, the flexible circuit board may be manufactured through processes such as photolithography, etching, electroplating, etc. Therefore, compared with the conventional flexible circuit board, the electronic device and the method for manufacturing the flexible circuit board of the disclosure may meet the needs of circuit miniaturization or thickness reduction. In some embodiments, the thickness of the seed layer may be greater than 0 μm and less than or equal to 1 μm. The seed layer may increase adhesion to the metal layer, and may also increase adhesion to the insulating layer, thereby enhancing the overall reliability of the flexible circuit board. The thickness of the conductive layer may be greater than or equal to 0.5 μm and less than or equal to 25 μm. The thickness of the insulating layer may be greater than 1 μm and less than or equal to 50 μm. The line width of the wires in the conductive layer may be greater than or equal to 2 μm. The line pitch of the wires in the conductive layer may be greater than or equal to 2 μm. Compared with the conventional flexible circuit board, the flexible circuit board of the disclosure may have a wider line width range, line pitch range or size design, i.e., a thinner line width, a narrower line pitch or a thinning feature may be achieved, and the flexible circuit board of the disclosure may be widely used in various electronic devices.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

Although the embodiments and advantages of the embodiments of the disclosure have been disclosed as above, it should be understood that any person skilled in the art, without departing from the spirit and scope of the disclosure, may make changes, substitutions and modifications, and the features of the embodiments may be arbitrarily mixed and replaced to form other new embodiments. Moreover, a protection scope of the disclosure is not limited to the processes, machines, manufacturing, material composition, devices, methods, and steps of the specific embodiments described in the specification, and any person skilled in the art should understand the processes, machines, manufacturing, material composition, devices, methods, and steps used currently or developed in the future from the content disclosed in the disclosure, as long as the substantially same functions may be implemented or the substantially same results may be obtained in the embodiments described herein. Therefore, the protection scope of the disclosure includes the above processes, machines, manufacturing, material composition, devices, methods, and steps. In addition, each claim constitutes an individual embodiment, and the protection scope of the disclosure also includes a combination of each claim and the embodiment. The protection scope of the disclosure is defined by the appended claims.

What is claimed is:

1. An electronic device, comprising:
a flexible circuit board, comprising:
a first flexible substrate;
a first seed layer, disposed on the first flexible substrate;
a first conductive layer, disposed on the first seed layer; and
a second seed layer, disposed on the first conductive layer,
wherein the first seed layer is in contact with the first conductive layer.

2. The electronic device as claimed in claim 1, wherein the first flexible substrate has an opening exposing the first seed layer.

3. The electronic device as claimed in claim 1, wherein a thickness of the first seed layer is greater than 0 μm and less than or equal to 1 μm.

4. The electronic device as claimed in claim 1, wherein a thickness of the first conductive layer is greater than or equal to 0.5 μm and less than or equal to 25 μm.

5. The electronic device as claimed in claim 1, wherein the first seed layer and the first conductive layer comprise a same material, and a grain size of the first seed layer is smaller than a grain size of the first conductive layer.

6. The electronic device as claimed in claim 1, wherein the second seed layer comprises:
a seed bottom layer, disposed on the first conductive layer and in contact with the first conductive layer; and
a seed top layer, disposed on the seed bottom layer and in contact with the seed bottom layer, wherein the seed top layer, the first seed layer, and the first conductive layer comprise a same material, and the seed top layer and the seed bottom layer comprise different materials.

7. The electronic device as claimed in claim 1, wherein the flexible circuit board further comprises an insulating layer, disposed on the first flexible substrate and the first conductive layer, the insulating layer has an opening exposing the first conductive layer, and the second seed layer is disposed on the insulating layer and contacts the first conductive layer through the opening.

8. The electronic device as claimed in claim 7, wherein a thickness of the insulating layer is greater than 1 μm and less than or equal to 50 μm.

9. The electronic device as claimed in claim 7, wherein the flexible circuit board further comprises another insulating layer, disposed between the insulating layer and the first flexible substrate, the another insulating layer has an opening, and the first seed layer is disposed on the another insulating layer and extends into the opening of the another insulating layer.

10. The electronic device as claimed in claim 7, wherein the flexible circuit board further comprises a second conductive layer, disposed on the second seed layer, and the second seed layer is in contact with the second conductive layer.

11. The electronic device as claimed in claim 10, wherein a thickness of the second conductive layer is greater than or equal to 0.5 μm and less than or equal to 25 μm.

12. The electronic device as claimed in claim 10, wherein the second seed layer and the second conductive layer comprise a same material, and a grain size of the second seed layer is smaller than a grain size of the second conductive layer.

13. The electronic device as claimed in claim 10, wherein the flexible circuit board further comprises a second flexible substrate, disposed on the insulating layer and the second conductive layer, and the second flexible substrate has an opening exposing the second conductive layer.

14. The electronic device as claimed in claim 1, wherein the flexible circuit board further comprises an auxiliary substrate, disposed on the first flexible substrate and exposing an opening of the first flexible substrate.

15. The electronic device as claimed in claim 13, wherein the flexible circuit board further comprises an auxiliary substrate, disposed on the second flexible substrate and at least exposing the opening of the second flexible substrate.

16. A method for manufacturing a flexible circuit board, comprising:
providing a non-flexible substrate;
disposing a first seed layer on the non-flexible substrate;
disposing a first conductive layer on the first seed layer; and
disposing a second seed layer on the first conductive layer.

17. The method for manufacturing the flexible circuit board as claimed in claim 16, further comprising:
disposing an insulating layer on the non-flexible substrate and the first conductive layer before disposing the second seed layer on the first conductive layer, wherein the insulating layer has an opening exposing the first conductive layer, and after the second seed layer is disposed on the first conductive layer, the second seed layer contacts the first conductive layer through the opening.

18. The method for manufacturing the flexible circuit board as claimed in claim 16, further comprising:
disposing a second conductive layer on the second seed layer; and
disposing a second flexible substrate on an insulating layer and the second conductive layer, wherein the second flexible substrate has an opening exposing the second conductive layer.

19. The method for manufacturing the flexible circuit board as claimed in claim 18, further comprising:
removing the non-flexible substrate; and
removing at least a part of the first seed layer.

20. The method for manufacturing the flexible circuit board as claimed in claim 19, further comprising:
forming a first flexible substrate under the first seed layer and the insulating layer, wherein the first flexible substrate has an opening exposing the first seed layer.
